(19) United States
(12) Patent Application Publication
(10) Pub. No.: US 2025/0251239 A1
(43) Pub. Date: Aug. 7, 2025

(54) SPINNING FIELD CONCENTRATOR MAGNETIC COMPASS

(71) Applicant: JEFFERSON SCIENCE ASSOCIATES, LLC, newport news, VA (US)

(72) Inventor: BOGDAN WOJTSEKHOWSKI, Yorktown, VA (US)

(21) Appl. No.: 19/066,439

(22) Filed: Feb. 28, 2025

Related U.S. Application Data
(60) Provisional application No. 63/627,913, filed on Feb. 1, 2024.

(51) Int. Cl. G01C 17/30; G01R 33/00; G01R 33/07

(52) U.S. Cl. CPC G01C 17/30; G01R 33/0029; G01R 33/072

(57) ABSTRACT

A high precision magnetic compass based on a stationary Hall probe and a spinning two-poles mu-metal field concentrator. The spinning poles lead to an oscillating magnetic field at the location of the Hall probe. The Hall probe sensitivity direction is oriented at an angle of 90 degrees to the rotation axis of the device. A second harmonic of oscillating component, or double frequency, of the signal from the probe, synchronized with the device rotation, is used to align the axis of rotation to be parallel to the magnetic field. The device does not require prior calibration. It is insensitive to drift of the probe parameters and can provide an angle with precision equal to or better than a 0.05 degree.

The United States Government may have certain rights to this invention under Management and Operating Contract No. DE-AC05-06OR23177 from the Department of Energy.

This application claims the priority of Provisional U.S. Patent Application Ser. No. 63/627,913 filed Feb. 1, 2024, the contents of which are incorporated herein by reference in their entirety.

### BACKGROUND OF THE INVENTION

In electron scattering studies of matter, there is a need to determine the magnetic field direction of the nuclei polarization in a target within 1 milliradian (mrad), which is equivalent to within 0.05 degree or better. The studies are typically carried out in an environment where the magnetic field is 25-30 Gauss.

Conventional 3D vector magnetometers typically cannot achieve this level of accuracy without frequent and costly calibration, and, due to limited stability, cannot provide required accuracy of the field direction in a magnetic field of this magnitude. Conventional arrow-based magnetic compasses are limited to an accuracy of 1-2 degrees, which is inadequate for scattering studies of particles at relativistic speeds.

Modern navigation for travel in the sea and air requires a magnetic compass with significantly better accuracy than the conventional compass provides. A high accuracy magnetic compass will be also a very useful tool for the exploration of outer space.

Although there have been disclosures of compasses using a rotating Hall probe they unfortunately require sliding contacts, such as a slip ring, which limits their accuracy and life time.

Accordingly, there is a need for a compass that achieves an accuracy of at least 1 mrad or 0.05 degree, and further is capable of a life time of 1000 hours or more for industrial applications.

### OBJECTS AND ADVANTAGES

A first object of the invention is to improve the precision in determining the magnetic field direction. The accuracy in determining the magnetic field direction needs to be 0.05 degree or better.

A second objective of the invention is to provide a compass which has demonstrated hundreds of hours of failure-free operation.

A third objective of the invention is to provide a compass which is sensitive to the direction of the field without prior calibration and temperature stabilization.

### BRIEF DESCRIPTION OF THE SEVERAL VIEWS OF THE DRAWING(S)

Reference is made herein to the accompanying drawings, which are not necessarily drawn to scale, and wherein:

FIG. 1 is an exploded isometric view of a spinning field concentrator magnetic compass according to the invention.

FIG. 2 is an end view of the compass from the Hall probe end.

FIG. 3 is a sectional view of the compass taken along line 3-3 of FIG. 2.

FIG. 4 displays test results of a prototype compass according to the invention including an upper panel displaying the rotation phase signal on an oscilloscope when the external transverse field is low (0.01 Gauss) and a lower panel displaying the signal from the Hall probe for the same time frame.

FIG. 5 displays test results of a prototype compass according to the invention including an upper panel displaying the rotation phase signal on the oscilloscope when the external transverse field is large (1.00 Gauss) and a lower panel displaying the signal from the Hall probe for the same time frame.

FIG. 6 is a plot of Fourier amplitude vs. frequency for a 0.01 Gauss transverse field. The peak at 16 Hz has a small amplitude (vertical scale is in dB).

FIG. 7 is a plot of Fourier amplitude vs. frequency for a 0.90 Gauss transverse field. The peak at 16 Hz has a large amplitude, about 100 times larger than in FIG. 6.

FIG. 8 is a plot of the Hall probe signal on an oscilloscope for a 0.25 Gauss transverse field. The signal was fitted with a five-parameter function to find the field value with high accuracy.

### DETAILED DESCRIPTION OF THE INVENTION

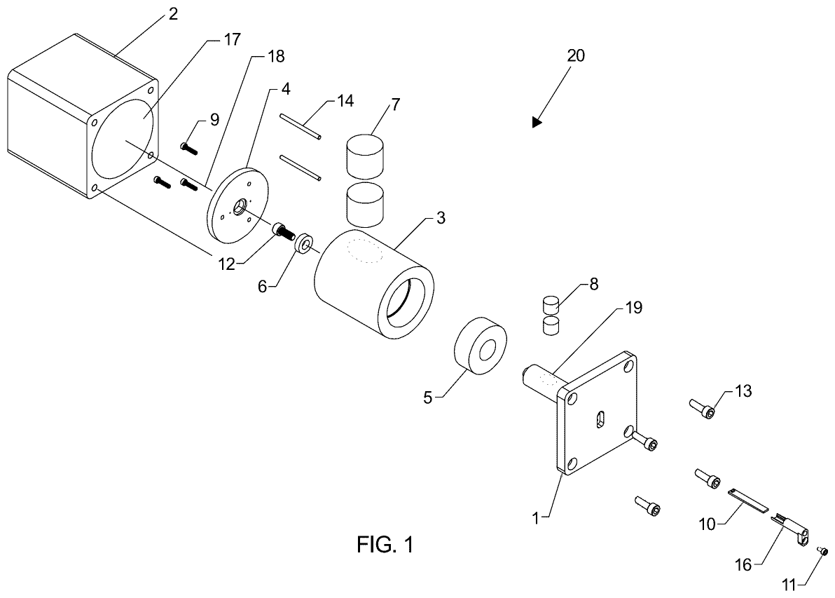

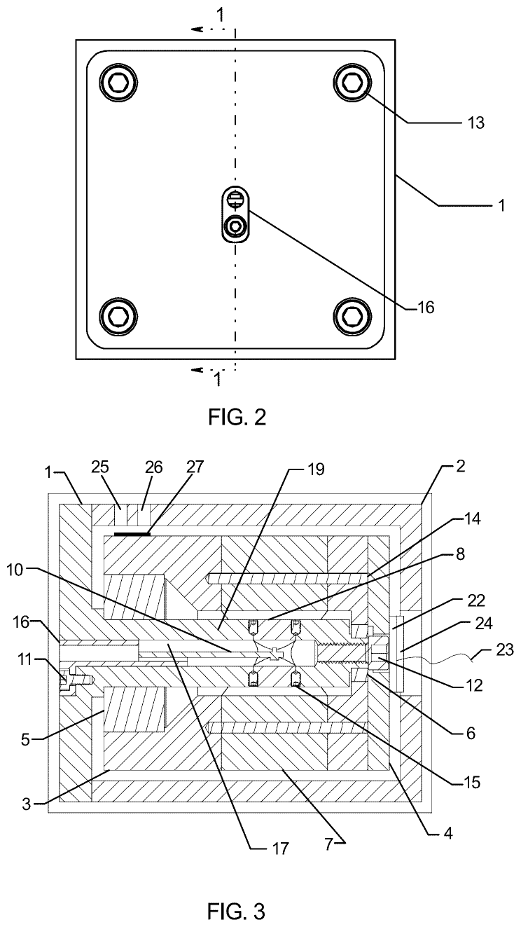

With reference to FIG. 1, the invention is a high precision compass 20 based on a stationary Hall probe 10 and a two-pole rotating field concentrator 8 of the magnetic field.

The compass includes a stationary part 1, a compass cover 2, a spinning mechanism or rotor 3, and a rotating mechanism cover 4. The compass also includes a back bearing 5, a front bearing 6, two rotating iron poles 7 secured by dowel pins 14 to the rotor 3, and a stationary iron poles 8. Bolts 9 secure the rotating mechanism cover 4 to the rotor 3. Compass cover 2 includes a housing cavity 17. The rotating poles are preferably constructed of mu-metal.

The Hall probe 10 sensitivity direction is oriented at an angle of 90 degrees to the rotation axis 18 of the rotor 3. An oscillating component of the signal from the probe 10 is due to magnetization of the rotating poles 7. The oscillating signal, synchronized with the poles 7 rotation, is used to decide how to align the axis of rotation of the spinning rotor 3. The second harmonic of the oscillating signal has a minimum (close to zero) when the axis of rotation is parallel to the magnetic field. The high precision magnetic compass 20 does not require prior calibration. It is insensitive to drift of the probe parameters and can provide an angle with precision on the level of at least 0.05 degrees.

With reference to FIG. 1, the Hall probe compass includes a non-rotation housing consisting of a compass cover 2 and a stationary part 1 forming a housing cavity 17 therein. The stationary part 1 and housing 2 are connected by bolts 13. Stationary part 1 includes a shaft 19 onto which a front bearing 6 and back bearing 5 are mounted. A rotor 3 is rotationally mounted within the housing cavity 17. The front bearing 6 secured by a bolt 12 to the stationary part 1. The front bearing 6 and the cover plate 4 with bolts 9 secure the rotor location. The back bearing 5 is secured between the stationary part 1 and the rotor 3. The rotor 3 includes two iron poles 7 which are fitted a rotor 3. A stationary part 1 includes two stationary iron poles 8.

As shown in FIG. 3, the stationary part 1 includes a shaft 19 and a cavity 17 for the Hall probe 10 which is supported by a bracket 16. A Hall probe plane is oriented orthogonal to the axis of the two stationary iron poles 8. The rotor 3 includes a spinning aluminum disk 22 that supports torque wires 23 and a flat mirror 24. The Hall probe compass includes a phase meter including a light emitting diode 25 and a photo resistor 26 each mounted in a hole on the compass cover 2 and a mirror 27 on the rotor 3.

In operation, an external motor (or air jet) provides rotation of the rotor 3. The rotating iron poles 7, magnetized by the external magnetic field, create an oscillating magnetic field. The Hall probe detects the component of the magnetic field orthogonal to the axis of rotation. A transverse component of magnetic field on the Hall probe has a component with a frequency twice larger than the rotor rotation frequency. The second harmonic component is due to the component of the external magnetic field orthogonal to the axis of rotation. Defects, if any, of the construction geometry have no impact on the second harmonic amplitude.

An oscillating component of the signal from the probe 10 is analyzed for the second harmonic amplitude. The compass is in alignment with the magnetic field direction when the second harmonic has zero amplitude.

The Hall probe 30 DRV5053 is a chopper-stabilized Hall Integrated Circuit (IC) that offers a magnetic sensing solution with sufficient stability over temperature and integrated protection features. The probe IC includes a 0- to 2-V analog output that responds linearly to the applied the magnetic field, and distinguishes the polarity of the magnetic field direction. Most preferably, the Hall probe is a DRV5053 analog-bipolar hall-effect sensor device available from Texas Instruments in Dallas, Texas. The Hall probe is sensitive to the magnetic field on a level of milli Gauss.

The task of the magnetic compass is to find the direction of the magnetic field, which is a vector, called here B. By definition, if any other vector, A, is parallel to B, the component of B orthogonal to A is equal to zero.

In a traditional compass the torque, which is able to rotate/align the arrow, is proportional to the component of magnetic field orthogonal to the arrow axis. The accuracy of alignment is limited by the friction in the arrow support in the device and the mismatch between the magnetic axis of the arrow and its mechanical shape.

In our U.S. Pat. No. 12,104,903 we observed the magnetic field by means of the Hall probe (HP), which was installed on a rotating body. Due to rotation of the HP, the observed signal oscillates. Alignment of the rotation axis with the magnetic field leads to minimization of the oscillating signal. Use of the oscillating signal is very advantageous due to its insensitivity to time/temperature instabilities of the HP device. The achievable accuracy is defined by the electronic noise and improves with larger integration time. In the case of a 25 Gauss external field, a sub milli radian accuracy was demonstrated within a few seconds. Unfortunately, in that patent, there was one component of the device which limited the rotation rate and accuracy. The limiting component was a slip ring needed for connecting the rotating HP (power wires and output) with the stationary electronics.

In the spinning field concentrator magnetic compass of the current invention, rotation of the HP, which is the main source of noise, is avoided but still provides an oscillating signal. The compass includes a magnetic field concentrator consisting of two iron poles mounted on the rotating cylinder. Operation of the compass includes aligning the axis of rotation with the magnetic field direction by observing the size of the HP oscillation signal.

The oscillating signal of the HP has the contributions from the transverse component of external magnetic field and from the residual magnetization of the iron poles. This residual magnetization, called a coercive force, is significant for ordinary steel but very low for the mu-metal (of 0.005 Gauss).

Importantly, the oscillating signal induced by residual magnetization has a frequency equal to the rotation frequency. At the same time, the external field, which we are interested in, concentrated by the poles has a double frequency. By using a five parameter mathematical procedure, we get the amplitude of the double frequency signal. Minimization of this second harmonic signal, amplitude of double frequency signal, allows us to align the axis of rotation with the external magnetic field.

The achievable rotation speed in the spinning field concentrator magnetic compass according to the invention could be as high as 100 revolutions per second and, with just 100 seconds integration, the achievable precision will be less than 0.1 milliradian for the Earth field case.

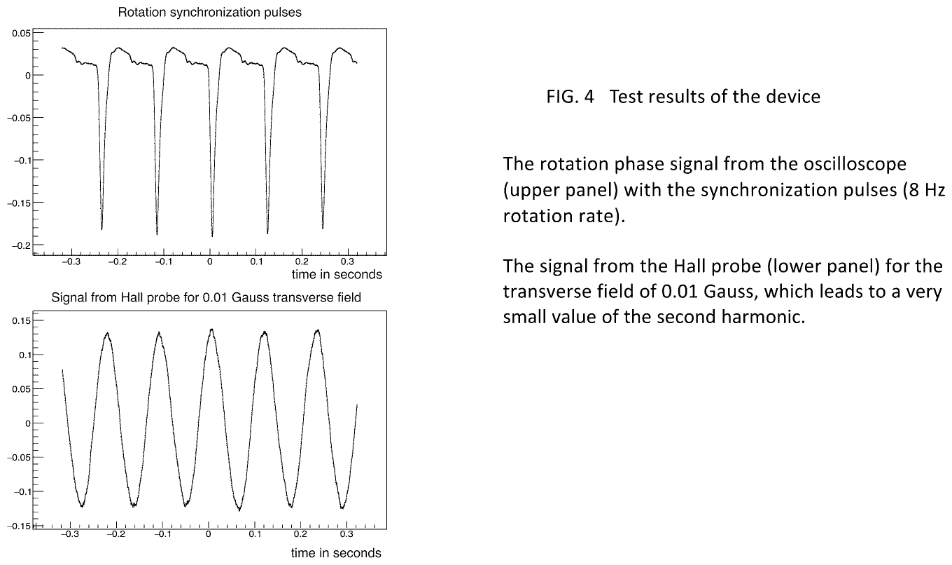

With reference to FIG. 4, test results of a prototype spinning field concentrator magnetic compass according to the invention include the signal from the oscilloscope in the upper panel with the synchronization pulses at 8 Hz rotation rate. The lower panel depicts the signal from the Hall probe for the transverse field of 0.01 Gauss, which leads to a very small value of the second harmonic. The poles for the prototype were made of soft iron for cost reduction. In the final device the Mu-metal should be used which reduce the size of the first harmonic signal.

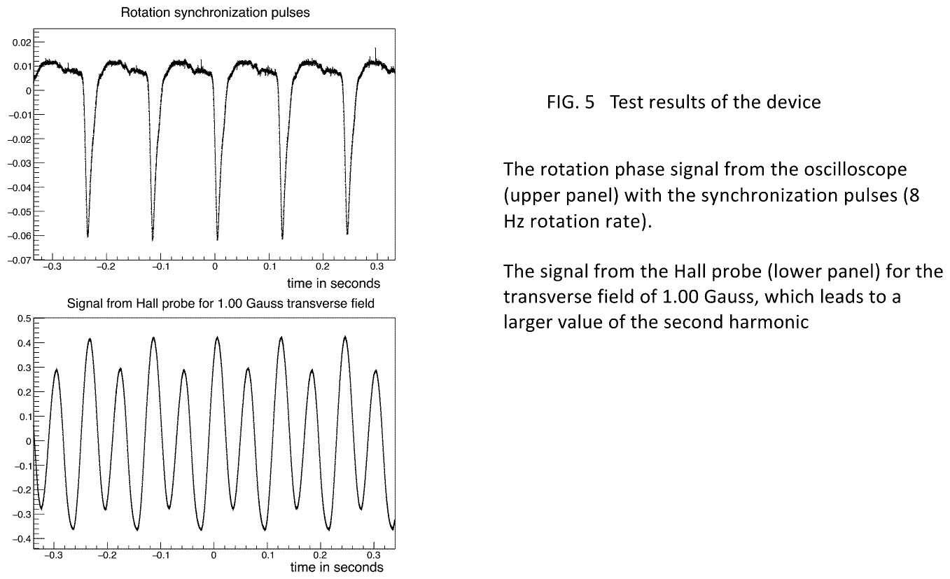

Referring to FIG. 5 test results of the prototype spinning field concentrator magnetic compass include the signal from the oscilloscope in the upper panel with the synchronization pulses (8 Hz rotation rate) and, in the lower panel, the signal from the Hall probe for the transverse field of 1.00 Gauss, which leads to a larger value of the second harmonic.

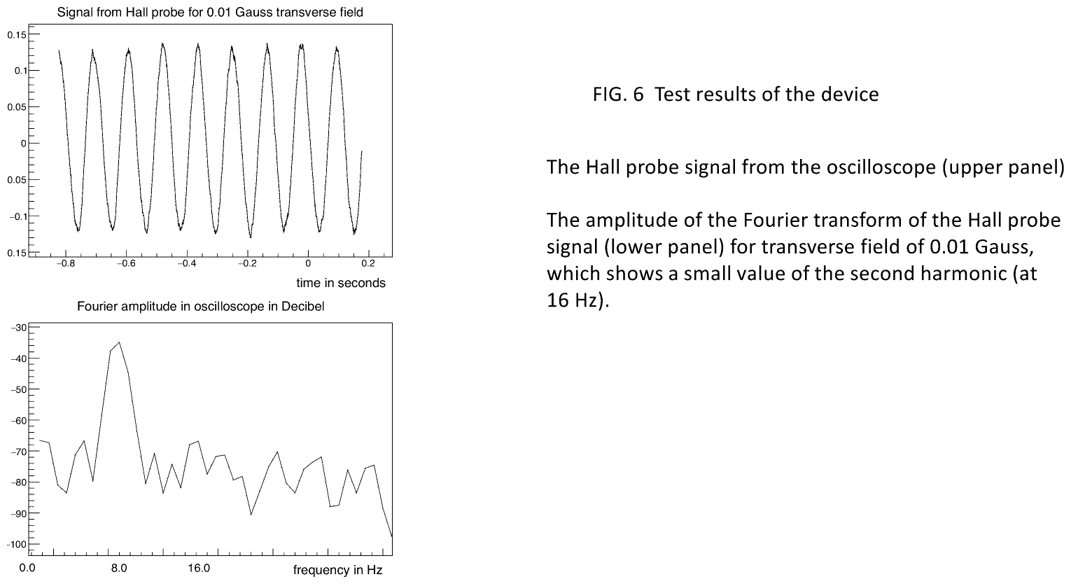

With reference to FIG. 6, test results of a prototype spinning field concentrator magnetic compass depict, in the upper panel, the Hall probe signal from the oscilloscope, and, in the lower panel, the amplitude of the Fourier transform of the Hall probe signal for transverse field of 0.01 Gauss, a small value of the second harmonic (at 16 Hz).

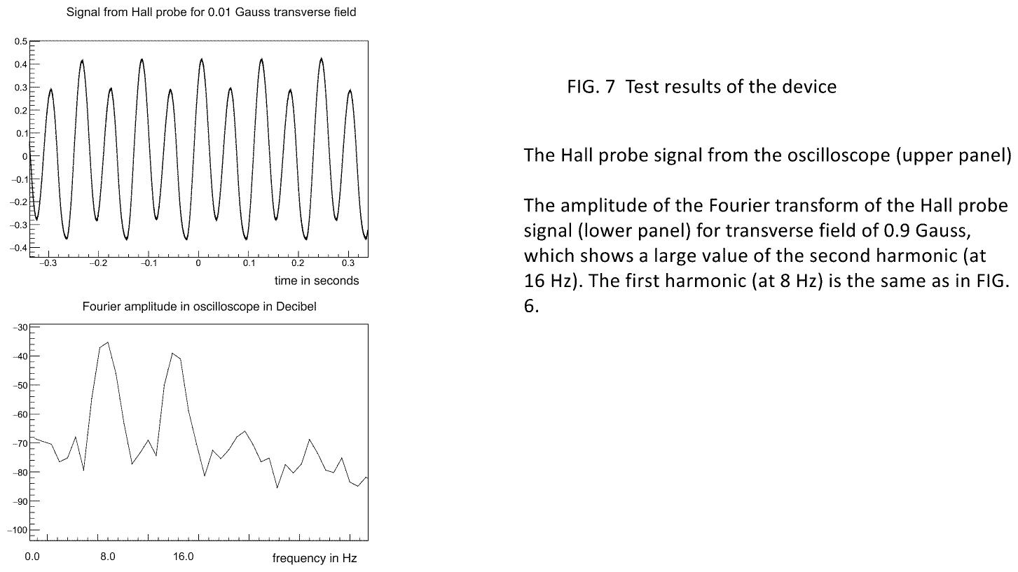

Referring to FIG. 7 test results of the protype compass show, in the upper panel, the Hall probe signal from the oscilloscope and, in the lower panel, the amplitude of the Fourier transform of the Hall probe signal for transverse field of 0.9 Gauss, which shows a large value of the second harmonic (at 16 Hz). The first harmonic (at 8 Hz) is also large as in FIG. 5.

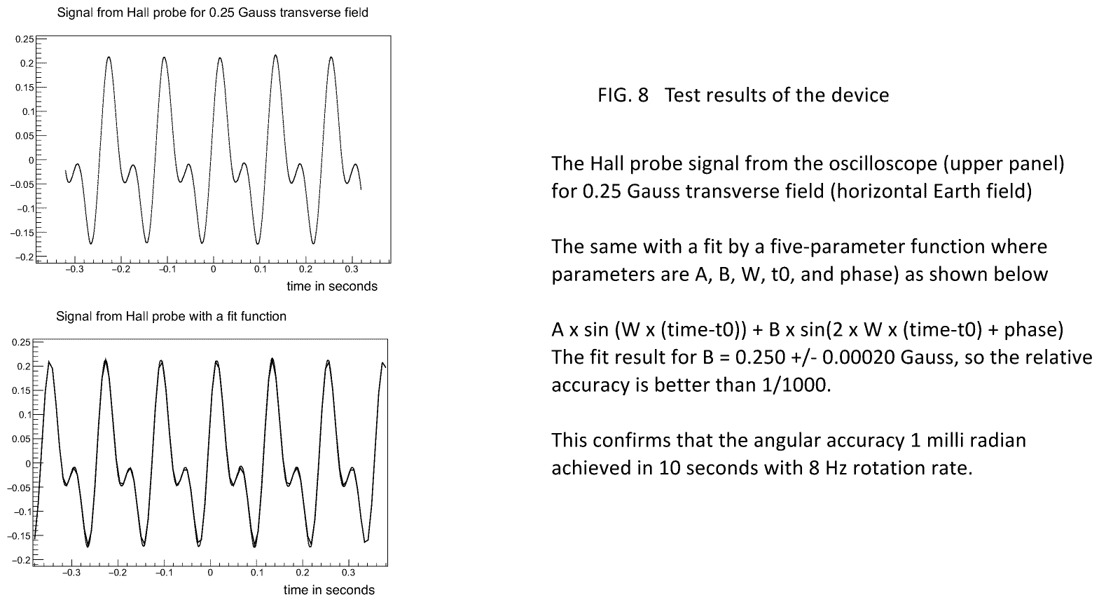

With reference to FIG. 8, test results of the Hall probe signal from the oscilloscope are shown for a 0.25 Gauss transverse field (horizontal Earth field) in the upper panel. The lower panel depicts the same with a fit by a five-parameter function A, B, W, t0, phase) according to the following:

$$A \times sin ( W \times ( time - t0 ) ) + B \times sin ( 2 \times W \times ( time - t 0 ) + phase ) .$$

The fit result for B=0.250+/−0.00020 Gauss, so the relative accuracy is better than 1/1000. This confirms that an angular accuracy of 1 milli radian is achieved in 10 seconds with 8 Hz rotation rate.

The description of the present invention has been presented for purposes of illustration and description, but is not intended to be exhaustive or limited to the invention in the form disclosed. Many modifications and variations will be apparent to those of ordinary skill in the art without departing from the spirit of the invention. The embodiments described herein were chosen and described in order to best explain the principles of the invention and the practical application, and to enable others of ordinary skill in the art to understand the invention for various embodiments while realizing that various modifications may be made to suit the particular use contemplated.

I claim:

1. A spinning field concentrator magnetic compass for determining the field direction in a magnetic field, comprising:
a non-rotation housing including a compass cover, and a stationary part, forming a housing cavity therein;
a rotor rotationally mounted within the housing cavity;
a Hall probe locked within the non-rotation housing; and
rotating iron poles with axis of rotation parallel to the plane of the Hall probe.

2. The compass of claim 1, comprising the Hall probe is sensitive to the magnetic field on a level of milli Gauss.

3. The compass of claim 1, comprising a rotation phase meter.

4. The compass of claim 3, comprising said rotation phase meter comprises:
an LED and photo-resistor; and
a mirror on the rotor.

5. The compass probe of claim 1, comprising Fourier analysis electronics for the Hall probe signal to determine the amplitude of a second harmonic.

6. The compass probe of claim 1, comprising electronics for the five-parameter function to determine the amplitude of a double frequency signal.

7. The compass probe of claim 5, comprising a display of the second harmonic amplitude averaged over 10 seconds.

8. The compass probe of claim 1, comprising two stationary poles of soft iron.

9. The compass probe of claim 1, comprising said spinning field concentrator magnetic compass provides an angular accuracy of 1 milli radian in 10 seconds with 8 Hz rotation rate.
